(19) United States
(12) Patent Application Publication
(10) Pub. No.: US 2026/0271652 A1
(43) Pub. Date: Sep. 10, 2026

(54) SUBSTRATE PROCESSING APPARATUS AND METHOD FOR CLEANING SUBSTRATE PROCESSING APPARATUS

(71) Applicant: Tokyo Electron Limited, Tokyo (JP)

(72) Inventors: Daisuke GOTO, Koshi-shi, Kumamoto (JP); Jiro HIGASHIJIMA, Koshi-shi, Kumamoto (JP); Nobuhiro OGATA, Koshi-shi, Kumamoto (JP); Kanta MORI, Koshi-shi, Kumamoto (JP); Kazunori NAKAMURA, Koshi-shi, Kumamoto (JP); Hiroki SAKURAI, Koshi-shi, Kumamoto (JP); Shoki MIZUGUCHI, Koshi-shi, Kumamoto (JP)

(21) Appl. No.: 19/164,797

(22) PCT Filed: Feb. 29, 2024
(86) PCT No.: PCT/JP2024/007583

§ 371 Date: Sep. 12, 2025

(30) Foreign Application Priority Data
Mar. 13, 2023 (JP) 2023-038900

(51) Int. Cl. H10P 72/00

(52) U.S. Cl. CPC H10P 72/0414; H10P 72/0408

(57) ABSTRACT

A substrate processing apparatus includes a processing chamber, a substrate holder which horizontally holds a substrate, a mist guard which externally surrounds a cup body for collecting a processing fluid scattering from the substrate, a nozzle which discharges the processing fluid toward the substrate, a cleaning liquid discharger which discharges a cleaning liquid toward the mist guard and the nozzle, a first remover which removes the cleaning liquid adhering to the mist guard, a second remover which removes the cleaning liquid adhering to the nozzle, and a controller which executes a first process of causing the cleaning liquid discharger to discharge the cleaning liquid toward the mist guard and the nozzle, a second process of causing the first remover to remove the cleaning liquid adhering to the mist guard, and a third process of causing the second remover to remove the cleaning liquid adhering to the nozzle.

### TECHNICAL FIELD

The present disclosure relates to a substrate processing apparatus and a method for cleaning a substrate processing apparatus.

### BACKGROUND

In a semiconductor device manufacturing process, when liquid processing such as wet etching is performed on a substrate such as a semiconductor wafer (hereinafter also referred to as a wafer) or the like, the processing liquid supplied to the substrate adheres to an inner wall surface of a processing chamber, and the like. Therefore, a technique for periodically washing off the processing liquid adhering to the inner wall surface of the processing chamber with a cleaning liquid is known in the related art (see Patent Document 1).

### Prior Art Document

### Patent Document

Patent Document 1: Japanese Laid-Open Patent Publication No. H11-297652

### SUMMARY

The present disclosure provides a technique capable of efficiently performing a process of cleaning a processing chamber.

A substrate processing apparatus according to an embodiment of the present disclosure includes a processing chamber, a substrate holder, a mist guard, a plurality of nozzles, a cleaning liquid discharger, a first remover, a second remover and a controller. The substrate holder is arranged inside the processing chamber and configured to horizontally hold a substrate. The mist guard externally surrounds a cup body configured to collect a processing fluid scattering from the substrate held by the substrate holder. The plurality of nozzles discharges the processing fluid toward the substrate held by the substrate holder. The cleaning liquid discharger discharges a cleaning liquid toward the mist guard and the plurality of nozzles. The first remover removes the cleaning liquid adhering to an upper surface of the mist guard. The second remover removes the cleaning liquid adhering to the plurality of nozzles. The controller controls the processing chamber, the substrate holder, the mist guard, the plurality of nozzles, the cleaning liquid discharger, the first remover, and the second remover. The controller executes a first process, a second process and a third process. The first process causes the cleaning liquid discharger to discharge the cleaning liquid toward the mist guard and the plurality of nozzles. The second process causes the first remover to remove the cleaning liquid adhering to the upper surface of the mist guard after the first process. The third process causes the second remover to remove the cleaning liquid adhering to the plurality of nozzles after the second process.

According to the present disclosure, it is possible to efficiently perform a process of cleaning a processing chamber.

### BRIEF DESCRIPTION OF DRAWINGS

FIG. 1 is a schematic diagram showing a schematic configuration of a substrate processing system according to an embodiment.

FIG. 2 is a schematic diagram showing an example of a specific configuration of the processing unit according to the embodiment.

FIG. 3 is a schematic diagram showing an example of the specific configuration of the processing unit according to the embodiment.

FIG. 4 is a diagram for explaining a first process in a cleaning process for the processing unit according to the embodiment.

FIG. 5 is a diagram for explaining a second process in the cleaning process for the processing unit according to the embodiment.

FIG. 6 is a diagram for explaining the second process in the cleaning process for the processing unit according to the embodiment.

FIG. 7 is a diagram for explaining the second process in the cleaning process for the processing unit according to the embodiment.

FIG. 8 is a diagram for explaining a third process in the cleaning process for the processing unit according to the embodiment.

FIG. 9 is a diagram for explaining the third process in the cleaning process for the processing unit according to the embodiment.

FIG. 10 is a diagram for explaining a fourth process in the cleaning process for the processing unit according to the embodiment.

FIG. 11 is a diagram for explaining the fourth process in the cleaning process for the processing unit according to the embodiment.

FIG. 12 is a diagram for explaining a fifth process in the cleaning process for the processing unit according to the embodiment.

FIG. 13 is a schematic diagram showing an example of a specific configuration of a processing unit according to a modification of the embodiment.

FIG. 14 is a diagram for explaining a second process in a cleaning process for the processing unit according to the modification of the embodiment.

FIG. 15 is a flowchart showing an example of a procedure of the cleaning process performed by the substrate processing system according to the embodiment.

### DETAILED DESCRIPTION

Hereinafter, embodiments of a substrate processing apparatus and a method for cleaning a substrate processing apparatus disclosed in the subject application will be described in detail with reference to the accompanying drawings. Further, the present disclosure is not limited to embodiments described below. In addition, it should be noted that the drawings are schematic, and the relationships between dimensions of respective elements, the ratios of the respective elements, and the like may differ from reality. Also, there may be a case where the relationship of dimensions and the ratios differ from each other between the drawings.

In a semiconductor device manufacturing process, when liquid processing such as wet etching is performed on a substrate such as a semiconductor wafer (hereinafter also referred to as a wafer) or the like, the processing liquid supplied to the substrate adheres to an inner wall surface of a processing chamber, and the like. Therefore, a technique for periodically washing off the processing liquid adhering to the inner wall surface of the processing chamber with a cleaning liquid is known in the related art.

However, in the above-mentioned technique in the related art, when internal components of the processing chamber are dried after cleaning an interior of the processing chamber with the cleaning liquid, the cleaning liquid remaining on one component may be accidentally scattered onto another component. This may make it difficult to efficiently perform the cleaning process for the processing chamber.

Therefore, a technique capable of overcoming the above-mentioned matters and efficiently performing a cleaning process for a processing chamber is needed.

### Overview of Substrate Processing System

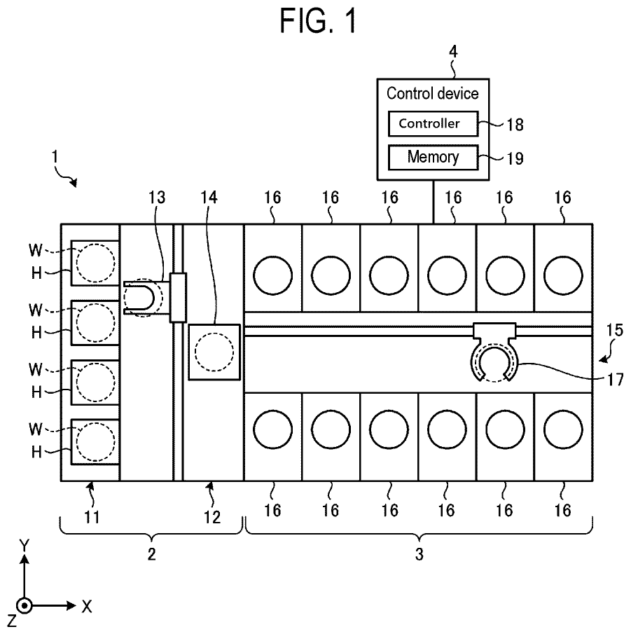

First, a schematic configuration of a substrate processing system 1 according to an embodiment will be described with reference to FIG. 1. FIG. 1 is a diagram showing the schematic configuration of the substrate processing system 1 according to the embodiment. For the clarification of a positional relationship, an X-axis direction, a Y-axis direction and a Z-axis direction, which are orthogonal to one another, are defined in the following description and a positive Z-axis direction is defined as a vertical upward direction.

As shown in FIG. 1, the substrate processing system 1 includes a loading/unloading station 2 and a processing station 3. The loading/unloading station 2 and the processing station 3 are provided adjacent to each other.

The loading/unloading station 2 includes a FOUP stage 11 and a transferor 12. A plurality of FOUPs H, each of which horizontally accommodates a plurality of substrates, that is, semiconductor wafers W (hereinafter referred to as wafers W) in this embodiment is placed on the FOUP stage 11.

The transferor 12 is provided adjacent to the FOUP stage 11, and includes a substrate transfer device 13 and a deliverer 14 which are arranged therein. The substrate transfer device 13 includes a wafer holding mechanism that holds the wafer W. The substrate transfer device 13 is capable of moving in horizontal and vertical directions and rotating about a vertical axis, and is configured to transfer the wafer W between the FOUP H and the deliverer 14 using the wafer holding mechanism.

The processing station 3 is provided adjacent to the transferor 12. The processing station 3 includes a transferor 15 and a plurality of processing units 16. The processing unit 16 is an example of a substrate processing apparatus. The plurality of processing units 16 are provided side by side on both sides of the transferor 15.

The transferor 15 includes a substrate transfer device 17 arranged therein. The substrate transfer device 17 includes a wafer holding mechanism that holds the wafer W. The substrate transfer device 17 is capable of moving in the horizontal and vertical directions and rotating about a vertical axis, and is configured to transfer the wafer W between the deliverer 14 and the processing units 16 using the wafer holding mechanism.

The processing unit 16 performs a given substrate processing on the wafer W transferred by the substrate transfer device 17.

The substrate processing system 1 further includes a control device 4. The control device 4 is, for example, a computer, and includes a controller 18 and a memory 19. The memory 19 stores programs for controlling various processes executed in the substrate processing system 1. The controller 18 controls an operation of the substrate processing system 1 by reading out and executing the programs stored in the memory 19.

The programs may be recorded in a computer-readable storage medium and installed from the storage medium in the memory 19 of the control device 4. Examples of the computer-readable storage medium may include a hard disk (HD), a flexible disk (FD), a compact disk (CD), a magnet optical disk (MO), and a memory card.

In the substrate processing system 1 configured as described above, first, the substrate transfer device 13 in the loading/unloading station 2 takes out the wafer W from the FOUP H placed on the FOUP stage 11, and places the taken-out wafer W on the deliverer 14. The wafer W placed on the deliverer 14 is taken out from the deliverer 14 by the substrate transfer device 17 in the processing station 3, and is loaded into the processing unit 16.

The wafer W loaded into the processing unit 16 is processed by the processing unit 16. Thereafter, the wafer W is unloaded from the processing unit 16 by the substrate transfer device 17 and placed on the deliverer 14. Thereafter, the processed wafer W placed on the deliverer 14 is returned to the FOUP H on the FOUP stage 11 by the substrate transfer device 13.

### Configuration of Processing Unit

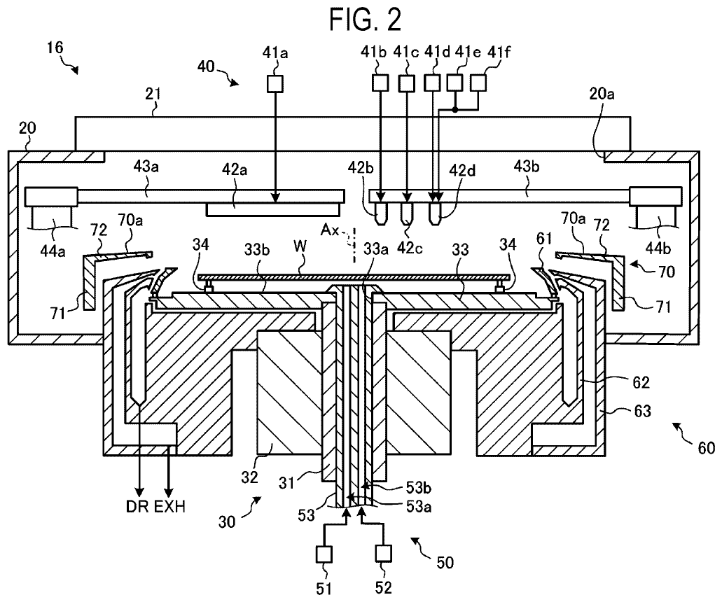

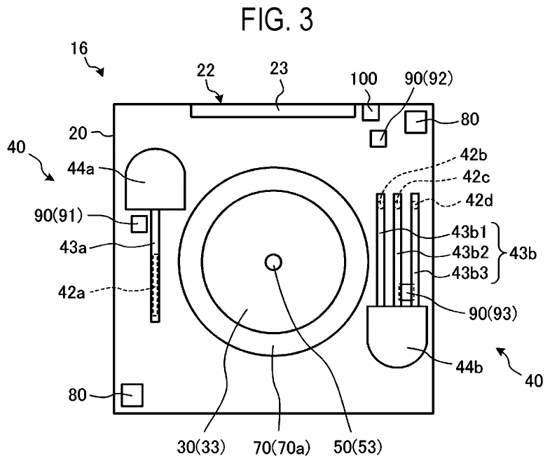

Next, a configuration of the processing unit 16 according to the embodiment will be described with reference to FIGS. 2 and 3. FIGS. 2 and 3 are schematic views showing an example of a specific configuration of the processing unit 16. FIG. 2 is a schematic cross-sectional view of the processing unit 16 as viewed from a side, and FIG. 3 is a schematic view of the processing unit 16 as viewed from above.

As shown in FIG. 2, the processing unit 16 includes a processing chamber 20, a rotary holder 30, an upper supply 40, a lower supply 50, a cup body 60, and a mist guard 70. In addition to the above-mentioned components, the processing unit 16 further includes a cleaning liquid discharger 80, a second remover 90, and a third remover 100, as shown in FIG. 3.

The processing chamber 20 is configured to process the wafer W with a processing fluid in the interior thereof. The processing chamber 20 accommodates the rotary holder 30, the upper supply 40, the lower supply 50, the cup body 60, the mist guard 70, the cleaning liquid discharger 80, the second remover 90, and the third remover 100.

As shown in FIG. 2, a FFU (fan filter unit) 21 is attached so as to cover an opening 20a formed in a ceiling wall of the processing chamber 20. The FFU 21 forms a down-flow in the interior of the processing chamber 20.

As shown in FIG. 3, a loading/unloading port 22 is formed in a sidewall of the processing chamber 20. The wafer W (see FIG. 2) is loaded into the processing chamber 20 via the loading/unloading port 22 and also unloaded from the processing chamber 20 via the loading/unloading port 22 by the substrate transfer device 17 (see FIG. 1).

A shutter 23 is provided at a position to close the loading/unloading port 22 and is configured to be able to open and close the loading/unloading port 22.

As shown in FIG. 2, the rotary holder 30 includes a rotary shaft 31, a drive 32, a substrate holder 33, and a plurality of support pins 34. The rotary shaft 31 is a hollow tubular member extending along the vertical direction. The rotary shaft 31 is configured to be rotatable around a central axis Ax.

The drive 32 is connected to the rotary shaft 31. The drive 32 operates based on a signal from the controller 18 (see FIG. 1) to rotate the rotary shaft 31. The drive 32 may be a power source such as an electric motor or the like.

The substrate holder 33 holds the wafer W horizontally. The substrate holder 33 is, for example, a flat plate having an annular shape, and extends horizontally. That is, a through-hole 33a is formed in a central portion of the substrate holder 33. An inner peripheral portion of the substrate holder 33 is connected to a tip portion of the rotary shaft 31. Therefore, the substrate holder 33 rotates around the central axis Ax of the rotary shaft 31 in conjunction with the rotation of the rotary shaft 31.

The plurality of support pins 34 are provided so as to protrude upward from the upper surface 33b of the substrate holder 33. The plurality of support pins 34 support the wafer W substantially horizontally by bringing the tips of the support pins 34 into contact with the rear surface of the wafer W. The support pins 34 may have, for example, a cylindrical shape or a frustum shape.

The plurality of support pins 34 may be arranged at approximately equal intervals in the vicinity of an outer periphery of the substrate holder 33 so as to form a circle as a whole when viewed from above. For example, when 12 support pins 34 are provided, they may be arranged at intervals of approximately 30 degrees.

The upper supply 40 supplies the processing fluid to an upper surface of the wafer W from above the wafer W. The upper supply 40 includes supplies 41a to 41f, nozzles 42a to 42d, arms 43a and 43b, and drives 44a and 44b. The nozzle 42b is an example of a first nozzle, the nozzle 42c is an example of a second nozzle, and the nozzle 42d is an example of a first remover.

The supply 41a includes a liquid source, a valve, a pump, and the like (all not shown), and supplies various processing liquids downward from the nozzle 42a based on a signal from the controller 18. The processing liquid supplied from the supply 41a is, for example, SPM (a mixture of sulfuric acid, hydrogen peroxide, and water).

The supply 41b includes a liquid source, a valve, a pump, and the like (all not shown), and supplies a drying liquid downward from the nozzle 42b based on a signal from the controller 18. The processing liquid supplied from the supply 41b is, for example, IPA (isopropyl alcohol).

The supply 41c includes a gas source, a valve, a pump, and the like (all not shown), and supplies various processing gases downward from the nozzle 42c based on a signal from the controller 18. The processing gas supplied from the supply 41c is, for example, an inert gas such as a nitrogen gas or the like.

The supply 41d includes a gas source, a valve, a pump, and the like (all not shown), and supplies various processing gases downward from the nozzle 42d based on a signal from the controller 18. The processing gas supplied from the supply 41d is, for example, an inert gas such as a nitrogen gas or the like.

The supply 41e includes a liquid source, a valve, a pump, and the like (all not shown), and supplies various processing liquids downward from the nozzle 42d based on a signal from the controller 18. The processing liquid supplied from the supply 41e is, for example, SC1 (a mixed liquid of ammonia, hydrogen peroxide, and water).

The supply 41f includes a liquid source, a valve, a pump, and the like (all not shown), and supplies various processing liquids downward from the nozzle 42d based on a signal from the controller 18. The processing liquid supplied from the supply 41f is, for example, DIW (deionized water).

The nozzle 42a is, for example, a bar nozzle, and is attached to the arm 43a. The arm 43a is located in a space above the rotary holder 30. The drive 44a raises and lowers the arm 43a in the vertical direction and rotates the arm 43a horizontally above the rotary holder 30 based on a signal from the controller 18.

The nozzles 42b, 42c, and 42d are attached to the arm 43b. For example, as shown in FIG. 3, the arm 43b is composed of three arms 43b1, 43b2, and 43b3. The nozzle 42b is attached to the arm 43b1, the nozzle 42c is attached to the arm 43b2, and the nozzle 42d is attached to the arm 43b3.

The nozzle 42d is, for example, a two-fluid nozzle, and is configured to mix the inert gas supplied from the supply 41d and the SC1 supplied from the supply 41e, and discharge a processing fluid thus mixed toward the wafer W.

As shown in FIG. 2, the arm 43b is located in the space above the rotary holder 30. The drive 44b raises and lowers the arm 43b in the vertical direction and rotates the arm 43b horizontally above the rotary holder 30 based on a signal from the controller 18.

The lower supply 50 supplies the processing fluid to a lower surface of the wafer W from below the wafer W. The lower supply 50 includes supplies 51 and 52 and a nozzle 53. The nozzle 53 is an example of a third nozzle.

The supply 51 includes a liquid source, a valve, a pump, and the like (all not shown), and supplies various processing liquids upward from the nozzle 53 based on a signal from the controller 18. The processing liquid supplied from the supply 51 is, for example, DIW (deionized water).

The supply 52 includes a gas source, a valve, a pump, and the like (all not shown), and supplies various processing gases upward from the nozzle 53 based on a signal from the controller 18. The processing gas supplied from the supply 52 is, for example, an inert gas such as a nitrogen gas or the like.

The cup body 60 is arranged so as to externally surround the substrate holder 33, and is configured to collect the processing fluid scattering from the wafer W held by the substrate holder 33. The cup body 60 includes, for example, an inner cup 61, a drainage cup 62, and an exhaust cup 63.

The inner cup 61 has, for example, an annular ring shape, and is arranged so as to externally surround the wafer W supported by the plurality of support pins 34. The inner cup 61 is supported, for example, on the upper surface 33b of the substrate holder 33. Therefore, the inner cup 61 rotates around the central axis Ax of the rotary shaft 31 in conjunction with the rotation of the rotary shaft 31.

In addition, since a gap exists between the inner cup 61 and the substrate holder 33, the processing fluid supplied to the wafer W passes through this gap and flows out of the inner cup 61 and the substrate holder 33. The inner cup 61 is not limited to being configured to be rotatable together with the substrate holder 33, and may be fixed to the processing chamber 20.

The drainage cup 62 is positioned so as to externally surround the inner cup 61. The drainage cup 62 forms a cylindrical space communicating with the gap between the inner cup 61 and the substrate holder 33, and collects the processing liquid flowing out from the gap. A pipe for discharging the collected processing liquid to a drainage part DR located outside the processing unit 16 is connected to a lower end portion of the drainage cup 62.

The exhaust cup 63 is positioned so as to externally surround the drainage cup 62. A cylindrical space is formed between the exhaust cup 63 and the drainage cup 62, and a pressure in the space is adjusted to a negative pressure. A pipe for suctioning atmosphere near the inner cup 61 and discharging the same to the exhaust part EXH located outside the processing unit 16 is connected to a lower end portion of the exhaust cup 63.

The mist guard 70 is positioned so as to externally surround the cup body 60. That is, the substrate holder 33 and the cup body 60 are positioned inside the mist guard 70. The mist guard 70 has, for example, a tubular portion 71 and a protruding portion 72.

The tubular portion 71 is, for example, cylindrical and extends in an up-down direction. The protruding portion 72 is, for example, annular and extends in the horizontal direction radially inward (that is, toward the cup body 60) from an upper end portion of the tubular portion 71. As a result, the protruding portion 72 forms an upper surface 70a of the mist guard 70.

The mist guard 70 is configured to be movable up and down by, for example, a lifting mechanism (not shown). The controller 18 may position the mist guard 70 at a high position to prevent mist of the processing liquid scattering from the rotating wafer W from reaching the inner wall of the processing chamber 20.

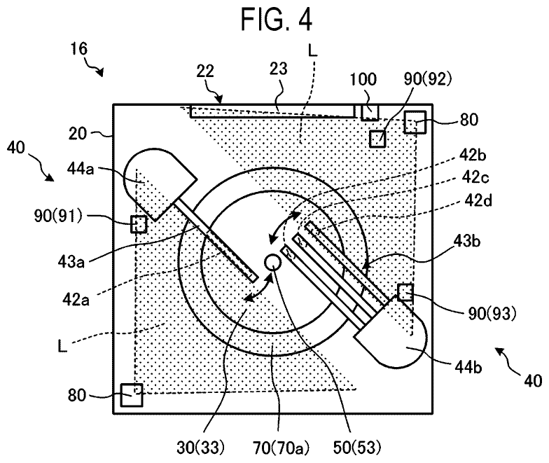

The cleaning liquid discharger 80 shown in FIG. 3 discharges a cleaning liquid L (see FIG. 4) toward the inner wall of the processing chamber 20 and each component located inside the processing chamber 20. The cleaning liquid L is, for example, DIW having room temperature or DIW having a high temperature.

As a result, the inner wall of the processing chamber 20 and each component located inside the processing chamber 20 are cleaned with the cleaning liquid L. Cleaning liquid dischargers 80 are provided, for example, near a pair of diagonal corners of the processing chamber 20 which has a rectangular shape in a plan view.

The second remover 90 removes the cleaning liquid L adhering to the nozzles 42a to 42d. For example, the second remover 90 removes the cleaning liquid L adhering to the nozzles 42a to 42d by discharging a drying gas G1 (see FIG. 8) toward the nozzles 42a to 42d.

The second remover 90 includes, for example, gas nozzles 91 to 93. The gas nozzle 91 is located, for example, near the drive 44a, to discharge the drying gas G1 from a base end side of the nozzle 42a toward the nozzle 42a.

The gas nozzle 92 is located, for example, at a position away from the drive 44a to discharge the drying gas G1 from a tip side of the nozzle 42a toward the nozzle 42a. The gas nozzle 93 is located, for example, near the drive 44b, to discharge the drying gas G1 toward the nozzles 42b, 42c, and 42d.

The third remover 100 removes the cleaning liquid L adhering to the shutter 23. For example, the third remover 100 removes the cleaning liquid L adhering to the shutter 23 by discharging the drying gas G1 toward the shutter 23. The third remover 100 is located, for example, near the shutter 23.

### Details of Cleaning Process

Next, details of the cleaning process for the processing unit 16 according to the embodiment will be described with reference to FIGS. 4 to 14. In the cleaning process for the processing unit 16 according to the embodiment, the controller 18 first executes a first process. FIG. 4 is a diagram for explaining the first process in the cleaning process for the processing unit 16 according to the embodiment.

As shown in FIG. 4, in the first process according to the embodiment, the controller 18 (see FIG. 1) operates the cleaning liquid discharger 80 to discharge the cleaning liquid L toward respective components in the processing chamber 20, including the mist guard 70, the nozzles 42a to 42d, and the shutter 23. As a result, the respective components in the processing chamber 20 are cleaned with the cleaning liquid L.

In the first process, the controller 18 may operate the drives 44a and 44b to reciprocate the nozzles 42a to 42d in the horizontal direction and also in the vertical direction. This makes it possible to efficiently clean the nozzles 42a to 42d.

Prior to the first process, the controller 18 may replace SC1 supplied from the supply 41e (see FIG. 2) with DIW supplied from the supply 41f (see FIG. 2) in an interior of the pipe connected to the nozzle 42d. This makes it possible to prevent SC1 from scattering from the nozzle 42d during a drying process for the nozzle 42d, which will be described later.

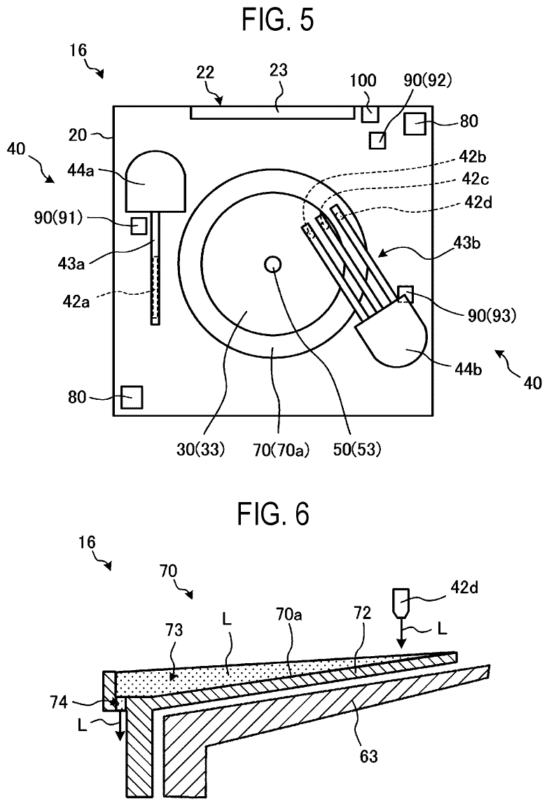

Next, the controller 18 executes a second process. FIGS. 5 to 7 are views for explaining the second process in the cleaning process for the processing unit 16 according to the embodiment.

In the second process according to the embodiment, as shown in FIG. 5, the controller 18 (see FIG. 1) operates the upper supply 40 to move the nozzle 42d to above the mist guard 70.

Then, as shown in FIG. 6, the controller 18 (see FIG. 1) causes DIW (that is, the cleaning liquid L) to be discharged from the nozzle 42d toward the upper surface 70a of the mist guard 70.

A recess 73 is formed in the upper surface 70a of the mist guard 70 according to the embodiment. The recess 73 is configured to be able to store the cleaning liquid L in the upper surface 70a. In addition, a discharge path 74 for discharging the cleaning liquid L stored in the recess 73 at a given flow rate is formed at a bottom of the recess 73 of the mist guard 70.

Then, the controller 18 operates the nozzle 42d to supply the cleaning liquid L at a flow rate greater than a flow rate at which the cleaning liquid L may be discharged from the discharge path 74, so that the cleaning liquid L is stored in the recess 73 so as to cover the upper surface 70a as shown in FIG. 6.

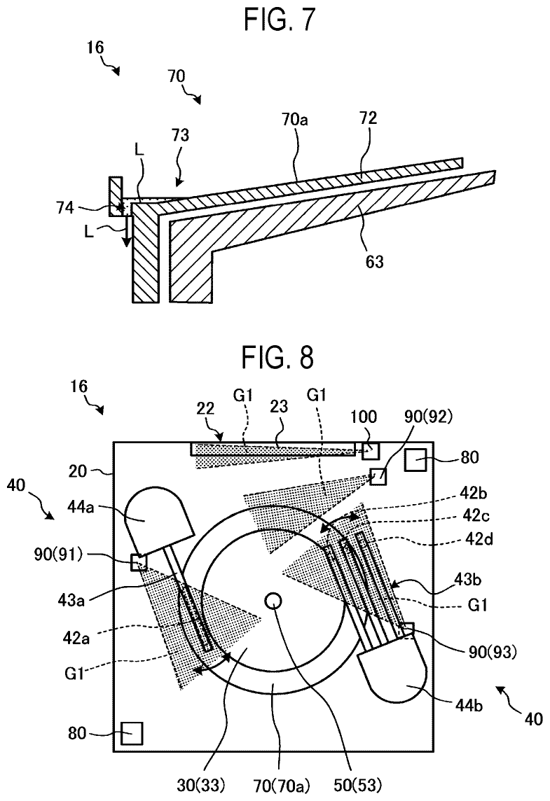

Further, when the cleaning liquid L is stored in the recess 73 so as to cover the upper surface 70a, the controller 18 stops the supply of the cleaning liquid L from the nozzle 42d. Then, as shown in FIG. 7, the cleaning liquid L stored in the recess 73 is gradually discharged from the discharge path 74.

At this time, in the embodiment, the cleaning liquid L in the recess 73 is discharged while forming one stream. The cleaning liquid L is discharged without leaving any droplet of the cleaning liquid L on the upper surface 70a. For example, in the embodiment, the cleaning liquid L stored in the recess 73 may be drained for a given period of time (for example, about one minute). The cleaning liquid L stored in the recess 73 may be discharged while forming one stream.

As described above, in the embodiment, the recess 73 and the discharge path 74 are provided in the mist guard 70, and the cleaning liquid L is supplied from the nozzle 42d to the recess 73, so that cleaning liquid L adhering to the upper surface 70a of the mist guard 70 may be removed in a simplified manner.

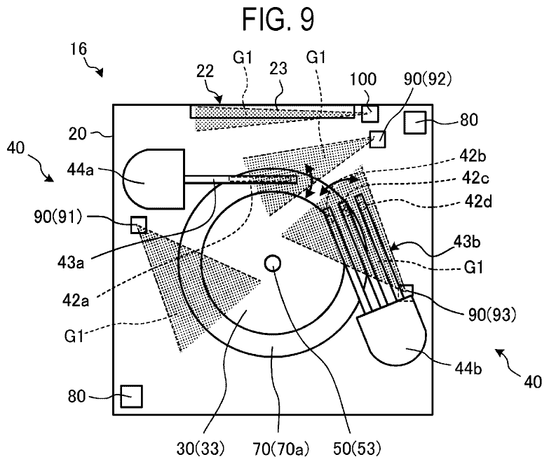

Next, the controller 18 executes a third process. FIGS. 8 and 9 are views for explaining the third process in the cleaning process for the processing unit 16 according to the embodiment.

As shown in FIG. 8, in the third process according to the embodiment, the controller 18 (see FIG. 1) operates the second remover 90 to discharge the drying gas G1 toward the nozzles 42a to 42d. In this way, the controller 18 removes the cleaning liquid L adhering to the nozzles 42a to 42d and dries the nozzles 42a to 42d.

For example, in the third process, the controller 18 operates the drive 44a to cause the nozzle 42a to reciprocate in the horizontal direction and also in the vertical direction in a discharge range of the gas nozzle 91.

As shown in FIG. 9, the controller 18 (see FIG. 1) operates the drive 44a to cause the nozzle 42a to reciprocate in the horizontal direction and also in the vertical direction in a discharge range of the gas nozzle 92.

In this manner, in the third process according to the embodiment, the drying gas G1 is discharged from both ends of the nozzle 42a, which is a bar nozzle, so that the nozzle 42a may be efficiently dried.

As shown in FIG. 8, in the third process, the controller 18 operates the drive 44b to cause the nozzles 42b to 42d to reciprocate in the horizontal direction and also in the vertical direction in a discharge range of the gas nozzle 93. This makes it possible to efficiently dry the nozzles 42b to 42d.

In the embodiment, it is preferable to dry the upper surface 70a of the mist guard 70 in advance by the above-mentioned second process before performing the third process. This makes it possible to prevent the cleaning liquid L remaining on the upper surface 70a of the mist guard 70 from accidentally adhering to the nozzles 42a to 42d when the nozzles 42a to 42d are caused to reciprocate in the horizontal and vertical directions in the third process.

Therefore, according to the embodiment, the cleaning process for the processing unit 16 may be efficiently performed.

According to the embodiment, in the third process, the nozzles 42a to 42d may be dried in a short time by discharging the drying gas G1 from the gas nozzles 91 to 93 of the second remover 90. Therefore, according to the embodiment, the cleaning process for the processing unit 16 may be efficiently performed.

According to the embodiment, in the third process, the shutter 23 may be dried together with the nozzles 42a to 42d by operating the third remover 100. This makes it possible to dry the nozzles 42a to 42d and the shutter 23 in a shorter time than when they are dried individually.

Therefore, according to the embodiment, the cleaning process for the processing unit 16 may be efficiently performed.

In the embodiment, a rain gutter (not shown) may be provided above the shutter 23 to prevent the cleaning liquid L from directly dropping onto the shutter 23 from above. This prevents the shutter 23 from becoming excessively wet with the cleaning liquid L during the first process, which makes it possible to dry the shutter 23 in a short time.

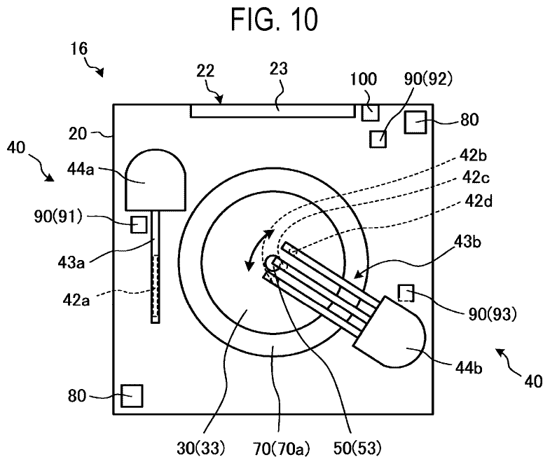

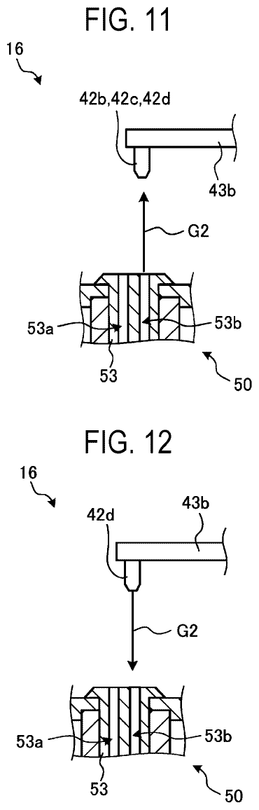

Following the third process described above, the controller 18 executes a fourth process. FIGS. 10 and 11 are views for explaining the fourth process in the cleaning process for the processing unit 16 according to the embodiment.

In the fourth process according to the embodiment, as shown in FIG. 10, the controller 18 (see FIG. 1) operates the drive 44b to cause the nozzles 42b to 42d to reciprocate in the horizontal direction and also in the vertical direction directly above the nozzle 53.

As shown in FIG. 11, the controller 18 (see FIG. 1) operates the lower supply 50 to discharge the inert gas G2 from the nozzle 53 to the nozzles 42b to 42d, thereby sufficiently drying the nozzles 42b to 42d.

Thus, in a case in which the wafer W is subjected to liquid processing after the drying process for the processing unit 16, when such a liquid-processed wafer W is dried using the nozzles 42b and 42c, it may be prevented from being contaminated by the cleaning liquid L remaining in the nozzles 42b to 42d.

Therefore, according to the embodiment, it is possible to suppress a decrease in yield of wafers W due to the cleaning process for the processing unit 16.

Next, the controller 18 executes a fifth process. FIG. 12 is a view for explaining the fifth process in the cleaning process for the processing unit 16 according to the embodiment.

In the fifth process according to the embodiment, as shown in FIG. 10, the controller 18 operates the drive 44b to cause the nozzle 42d to reciprocate in the horizontal direction directly above the nozzle 53.

As shown in FIG. 12, the controller 18 (see FIG. 1) operates the upper supply 40 to discharge the inert gas G2 from the nozzle 42d to the nozzle 53. This makes it possible to sufficiently dry the nozzle 53.

Then, after the fifth process is completed, the controller 18 replaces DIW supplied from the supply 41f (see FIG. 2) with SC1 supplied from the supply 41e (see FIG. 2) in the interior of the pipe connected to the nozzle 42d, and completes a series of cleaning processes.

In the embodiment described so far, the example has been shown in which the upper surface 70a of the mist guard 70, on which the recess 73 and the discharge path 74 are formed, is dried by supplying the cleaning liquid L to the upper surface 70a of the mist guard 70. However, the present disclosure is not limited thereto.

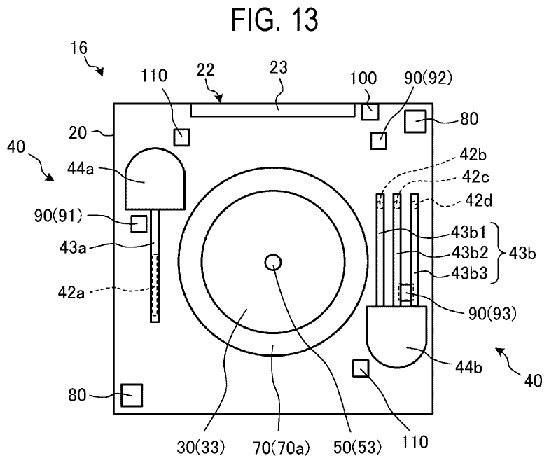

FIG. 13 is a schematic diagram showing an example of a specific configuration of a processing unit 16 according to a modification of the embodiment. As shown in FIG. 13, the processing unit 16 according to the modification is different from the above-described embodiment (see FIG. 3) in that a gas nozzle 110 is provided.

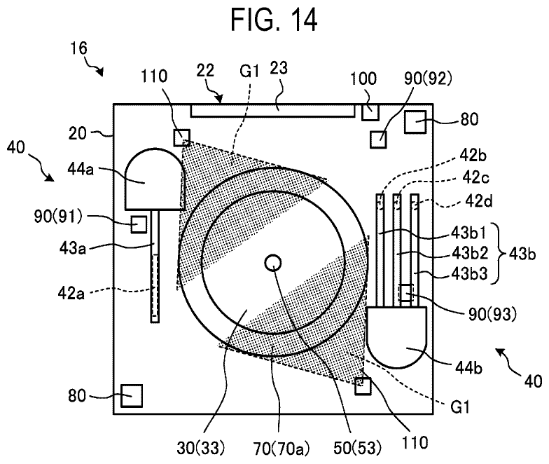

The gas nozzle 110 is another example of the first remover. For example, a plurality of gas nozzles (two gas nozzles in FIG. 13) are provided around the mist guard 70. The gas nozzle 110 discharges the drying gas G1 (see FIG. 14) from the outer periphery of the mist guard 70 toward the upper surface 70a of the mist guard 70.

FIG. 14 is a diagram for explaining a second process in the cleaning process for the processing unit 16 according to the modification of the embodiment. In the second process according to the modification, the controller 18 operates the gas nozzle 110 to discharge the drying gas G1 from the gas nozzle 110 toward the upper surface 70a of the mist guard 70. This dries the upper surface 70a of the mist guard 70.

By drying the upper surface 70a of the mist guard 70 in advance prior to the third process of drying the nozzles 42a to 42d, it is possible to prevent the cleaning liquid L remaining on the upper surface 70a of the mist guard 70 from adhering to the nozzles 42a to 42d during the third process. Therefore, according to this modification, it is possible to efficiently perform the cleaning process for the processing unit 16.

In addition, in this modification, by discharging the drying gas G1 from the gas nozzle 110 toward the upper surface 70a of the mist guard 70, the cleaning liquid L adhering to the upper surface 70a of the mist guard 70 may be removed in a short time.

The substrate processing apparatus (the processing unit 16) according to the embodiment includes the processing chamber 20, the substrate holder 33, the mist guard 70, the nozzles 42a to 42d, the cleaning liquid discharger 80, the first remover (the nozzle 42d and the gas nozzle 110), the second remover 90, and the controller 18. The substrate holder 33 is arranged inside the processing chamber 20 and configured to horizontally hold the substrate (wafer W). The mist guard 70 externally surrounds the cup body 60 that collects the processing fluid scattering from the substrate (wafer W) held by the substrate holder 33. The nozzles 42a to 42d discharge the processing fluid toward the substrate (wafer W) held by the substrate holder 33. The cleaning liquid discharger 80 discharges the cleaning liquid L toward the mist guard 70 and the nozzles 42a to 42d. The first remover (the nozzle 42d and the gas nozzle 110) removes the cleaning liquid L adhering to the upper surface 70a of the mist guard 70. The second remover 90 removes the cleaning liquid L adhering to the nozzles 42a to 42d. The controller 18 controls the respective parts. The controller 18 also executes the first process, the second process, and the third process. In the first process, the cleaning liquid discharger 80 discharges the cleaning liquid L toward the mist guard 70 and the nozzles 42a to 42d. In the second process after the first process, the first remover (the nozzle 42d and the gas nozzle 110) removes the cleaning liquid L adhering to the upper surface 70a of the mist guard 70. In the third process after the second process, the second remover 90 removes the cleaning liquid L adhering to the nozzles 42a to 42d. This makes it possible to efficiently perform the cleaning process for the processing unit 16.

In the substrate processing apparatus (the processing unit 16) according to this embodiment, the second remover 90 includes the gas nozzles 91 to 93 configured to discharge the drying gas G1 to the nozzles 42a to 42d. This makes it possible to dry the nozzles 42a to 42d in a short time.

Further, in the substrate processing apparatus (the processing unit 16) according to the embodiment, the mist guard 70 includes the recess 73 configured to be able to store the cleaning liquid L on the upper surface 70a thereof, and the discharge path 74 configured to discharge the cleaning liquid L stored in the recess 73. Further, the first remover is the nozzle 42d configured to discharge the cleaning liquid L into the recess 73. This makes it possible to easily remove the cleaning liquid L adhering to the upper surface 70a of the mist guard 70.

In the substrate processing apparatus (the processing unit 16) according to the embodiment, the first remover is the gas nozzle 110 configured to discharge the drying gas G1 toward the upper surface 70a of the mist guard 70. This makes it possible to remove the cleaning liquid L adhering to the upper surface 70a of the mist guard 70 in a short time.

Further, in the substrate processing apparatus (the processing unit 16) according to the embodiment, the processing chamber 20 includes the loading/unloading port 22 through which the substrate (the wafer W) is loaded and unloaded, and the shutter 23 configured to close the loading/unloading port 22. Further, the substrate processing apparatus (the processing unit 16) according to the embodiment further includes the third remover 100 configured to remove the cleaning liquid L adhering to the shutter 23. Then, in the third process, the controller 18 removes the cleaning liquid L adhering to the shutter 23 by the third remover 100. This makes it possible to efficiently perform the cleaning process for the processing unit 16.

In the substrate processing apparatus (the processing unit 16) according to the embodiment, the nozzles 42a to 42d include the first nozzle (the nozzle 42b) and the second nozzle (the nozzle 42c). The first nozzle (the nozzle 42b) discharges the drying liquid for drying the substrate (the wafer W) toward the substrate (the wafer W). The second nozzle (the nozzle 42c) discharges the inert gas G2 toward the substrate (the wafer W). The substrate processing apparatus (the processing unit 16) according to the embodiment further includes the third nozzle (the nozzle 53) configured to discharge the inert gas G2 toward the rear surface of the substrate (the wafer W). Thereafter, the controller 18 executes the fourth process after the third process. In the fourth process, the third nozzle (the nozzle 53) discharges the inert gas G2 toward the first nozzle (nozzle 42b) and the second nozzle (the nozzle 42c) to dry the first nozzle (nozzle 42b) and the second nozzle (the nozzle 42c). This makes it possible to prevent the yield of the wafer W from being adversely reduced by the cleaning process for the processing unit 16.

In the substrate processing apparatus (the processing unit 16) according to the embodiment, after the fourth process, the controller 18 executes the fifth process of discharging the inert gas G2 from the second nozzle (the nozzle 42c) to the third nozzle (the nozzle 53) to dry the third nozzle (the nozzle 53). This makes it possible to sufficiently dry the nozzle 53.

### Procedure of Cleaning Process

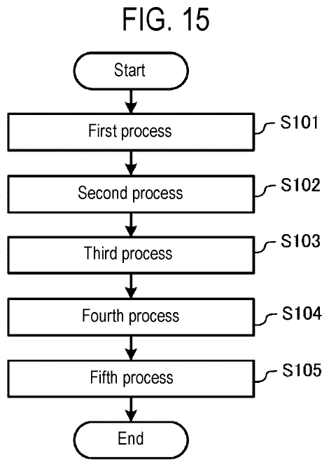

Next, a procedure of the cleaning process for the processing unit 16 according to the embodiment will be described with reference to FIG. 15. FIG. 15 is a flowchart showing an example of the procedure of the cleaning process performed by the substrate processing system 1 according to the embodiment.

In the cleaning process of the embodiment, first, the controller 18 controls the cleaning liquid discharger 80 and the like to perform the first process of discharging the cleaning liquid L toward respective parts such as the mist guard 70 and the nozzles 42a to 42d included in the processing chamber 20 (Step S101).

Next, the controller 18 controls the upper supply 40 or the gas nozzle 110 to execute the second process of removing the cleaning liquid L adhering to the upper surface 70a of the mist guard 70 (Step S102).

Next, the controller 18 controls the second remover 90 and the like to perform the third process of removing the cleaning liquid L adhering to the nozzles 42a to 42d (Step S103). Then, the controller 18 controls the lower supply 50 and the like to discharge the inert gas G2 from the nozzle 53 to the nozzles 42b to 42d and perform the fourth process of drying the nozzles 42b to 42d (Step S104).

Lastly, the controller 18 controls the upper supply 40 and the like to discharge the inert gas G2 from the nozzle 42d to the nozzle 53, and executes the fifth process of drying the nozzle 53 (Step S105). In this way, the series of cleaning processes ends.

The method for cleaning the substrate processing apparatus (the processing unit 16) according to the embodiment includes a first operation (Step S101), a second operation (Step S102), and a third operation (Step S103). In the first operation (Step S101), the cleaning liquid L is discharged toward the mist guard 70 that externally surrounds the cup body 60 and collects the processing fluid scattering from the substrate held by the substrate holder 33, and toward the nozzles 42a to 42d that discharge the processing fluid toward the substrate held by the substrate holder 33. In the second operation (Step S102) after the first operation (Step S101), the cleaning liquid L adhering to the upper surface 70a of the mist guard 70 is removed. In the third operation (Step S103) after the second operation (Step S102), the cleaning liquid L adhering to the nozzles 42a to 42d is removed. This makes it possible to efficiently perform the cleaning process for the processing unit 16.

Although the embodiments of the present disclosure have been described above, the present disclosure is not limited to the above-described embodiments, and various modifications may be made without departing from the spirit of the present disclosure.

The embodiments described herein should be considered to be exemplary and not limitative in all respects. Indeed, the above-described embodiments may be embodied in various forms. Further, the above-described embodiments may be omitted, substituted, or modified in various forms without departing from the scope and spirit of the appended claims.

### EXPLANATION OF REFERENCE NUMERALS

W: wafer (example of substrate), 1: substrate processing system, 16: processing unit (example of substrate processing apparatus), 20: processing chamber, 22: loading/unloading port, 23: shutter, 33: second holder, 42a: nozzle, 42b: nozzle (example of nozzle and first nozzle), 42c: nozzle (example of nozzle and second nozzle), 42d: nozzle (example of nozzle and first remover), 53: nozzle (example of third nozzle), 60: cup body, 70: mist guard, 70a: upper surface, 73: recess, 74: discharge path, 80: cleaning liquid discharger, 90: second remover, 91 to 93: gas nozzle, 100: third remover, 110: gas nozzle (example of first remover), L: cleaning liquid, G1: drying gas, G2: inert gas

1-8. (canceled)

9. A substrate processing apparatus, comprising:
a processing chamber;
a substrate holder arranged inside the processing chamber and configured to horizontally hold a substrate;
a mist guard configured to externally surround a cup body configured to collect a processing fluid scattering from the substrate held by the substrate holder;
a plurality of nozzles configured to discharge the processing fluid onto the substrate held by the substrate holder;
a cleaning liquid discharger configured to discharge a cleaning liquid toward the mist guard and the plurality of nozzles;
a first remover configured to remove the cleaning liquid adhering to an upper surface of the mist guard;
a second remover configured to remove the cleaning liquid adhering to the plurality of nozzles; and
a controller configured to control the processing chamber, the substrate holder, the mist guard, the plurality of nozzles, the cleaning liquid discharger, the first remover, and the second remover,
wherein the controller executes a first process of causing the cleaning liquid discharger to discharge the cleaning liquid toward the mist guard and the plurality of nozzles, a second process of causing the first remover to remove the cleaning liquid adhering to the upper surface of the mist guard after the first process, and a third process of causing the second remover to remove the cleaning liquid adhering to the plurality of nozzles after the second process.

10. The substrate processing apparatus of claim 9, wherein the second remover includes a gas nozzle configured to discharge a drying gas to the plurality of nozzles.

11. The substrate processing apparatus of claim 9, wherein the mist guard has a recess configured to store the cleaning liquid on the upper surface, and a discharge path configured to discharge the cleaning liquid stored in the recess, and
wherein the first remover is one of the plurality of nozzles configured to discharge the cleaning liquid into the recess.

12. The substrate processing apparatus of claim 9, wherein the first remover includes a gas nozzle configured to discharge a drying gas toward the upper surface of the mist guard.

13. The substrate processing apparatus of claim 9, wherein the processing chamber includes a loading/unloading port through which the substrate is loaded and unloaded and a shutter configured to close the loading/unloading port,
the substrate processing apparatus further comprising: a third remover configured to remove the cleaning liquid adhering to the shutter,
wherein the controller controls the third remover to remove the cleaning liquid adhering to the shutter during the third process.

14. The substrate processing apparatus of claim 9, wherein the plurality of nozzles includes a first nozzle configured to discharge a drying processing liquid onto the substrate to dry the substrate, and a second nozzle configured to discharge an inert gas toward the substrate,
wherein the plurality of nozzles further includes a third nozzle configured to discharge the inert gas toward a rear surface of the substrate, and
wherein the controller executes a fourth process of, after the third process, discharging the inert gas from the third nozzle toward the first nozzle and the second nozzle to dry the first nozzle and the second nozzle.

15. The substrate processing apparatus of claim 14, wherein the controller executes a fifth process of, after the fourth process, discharging the inert gas from the second nozzle toward the third nozzle to dry the third nozzle.

16. The substrate processing apparatus of claim 10, wherein the mist guard has a recess configured to store the cleaning liquid on the upper surface, and a discharge path configured to discharge the cleaning liquid stored in the recess, and
wherein the first remover is one of the plurality of nozzles configured to discharge the cleaning liquid into the recess.

17. The substrate processing apparatus of claim 10, wherein the first remover includes a gas nozzle configured to discharge a drying gas toward the upper surface of the mist guard.

18. The substrate processing apparatus of claim 10, wherein the processing chamber includes a loading/unloading port through which the substrate is loaded and unloaded and a shutter configured to close the loading/unloading port,
the substrate processing apparatus further comprising: a third remover configured to remove the cleaning liquid adhering to the shutter,
wherein the controller controls the third remover to remove the cleaning liquid adhering to the shutter during the third process.

19. The substrate processing apparatus of claim 10, wherein the plurality of nozzles includes a first nozzle configured to discharge a drying processing liquid onto the substrate to dry the substrate, and a second nozzle configured to discharge an inert gas toward the substrate,
wherein the plurality of nozzles further includes a third nozzle configured to discharge the inert gas toward a rear surface of the substrate, and
wherein the controller executes a fourth process of, after the third process, discharging the inert gas from the third nozzle toward the first nozzle and the second nozzle to dry the first nozzle and the second nozzle.

20. A method for cleaning a substrate processing apparatus, the method comprising:
a first operation of discharging a cleaning liquid toward a mist guard configured to externally surround a cup body which collects a processing fluid scattering from a substrate held by a second holder, and a nozzle configured to discharge the processing fluid toward the substrate held by the second holder;
a second operation of removing the cleaning liquid adhering to an upper surface of the mist guard after the first operation; and
a third operation of removing the cleaning liquid adhering to the nozzle after the second operation.
